(19) United States
(12) Patent Application Publication
(10) Pub. No.: US 2023/0245944 A1
(43) Pub. Date: Aug. 3, 2023

(54) FAN-OUT TYPE PACKAGE PREPARATION METHOD OF FAN-OUT TYPE PACKAGE

(71) Applicant: Institute of Semiconductors, Guangdong Academy of Sciences, Guangzhou (CN)

(72) Inventors: Yingqiang Yan, Guangzhou (CN); Chuan Hu, Guangzhou (CN); Zhikuan Chen, Guangzhou (CN); Zhitao Chen, Guangzhou (CN)

(21) Appl. No.: 17/635,437

(22) PCT Filed: Jul. 28, 2021
(86) PCT No.: PCT/CN2021/108981

§ 371 Date: Feb. 15, 2022

(51) Int. Cl. H01L 23/367; H01L 23/29; H01L 21/56

(52) U.S. Cl. CPC H01L 23/3675; H01L 23/29; H01L 21/56

(57) ABSTRACT

A fan-out type package and a preparation method of the fan-out type package are provided. The fan-out type package has one or more chips having same or different functions and each having a back surface mounted in a chip mounting region of the heat dissipation sheet via the adhesive material layer, and a front surface covered by a temporary protection material; an adhesive material layer; a heat dissipation sheet; an encapsulation material layer formed by making an encapsulation material flow into and fill a gap between the temporary protection material and the heat dissipation sheet and/or cover a side of the heat dissipation sheet opposite to a side thereof mounted with the chip, and then removing the temporary protection material; a packaging circuit grown on the front surface of the chip, the encapsulation material, and the heat dissipation sheet; and a packaging circuit protection layer protecting the packaging circuit.

### CROSS REFERENCE TO RELATED APPLICATIONS

The present application claims the priority benefit of International Patent Application No. PCT/CN2021/108981, filed Jul. 28, 2021.

### BACKGROUND AND FIELD OF THE INVENTION

The present disclosure relates to the field of chip packaging, in particular, to a fan-out type package capable of realizing good heat dissipation, improving operation power and reducing power consumption of devices, and being applicable to chips with a high power density, and a preparation method of the fan-out type package.

As electronic products are developed towards the direction of becoming smaller and smaller, intelligent, and having high performance and high reliability, chips with a high power density also need to be smaller, intelligent, and systematic. A conventional packaging method of a chip with a high power density comprises: attaching the chip on a circuit substrate, performing electrical interconnection through a lead bonding process, and then performing packaging. This has problems such as a large packaging volume, poor heat dissipation, and a very high operating temperature, which is generally greater than 130° C., a large power loss, and poor reliability of a device on the substrate. Moreover, this method is not suitable for integrating chips that cannot withstand high temperature.

### SUMMARY OF THE INVENTION

In view of the above situations, the present disclosure is proposed, with an objective of providing a fan-out type package having good heat dissipation performance, being capable of improving operation power and reducing power consumption of devices, and being applicable to chips with a high power density, and a preparation method of the fan-out type package.

In order to solve the above problems, the present disclosure provides a fan-out type package, having one or two or more chips having the same or different functions, an adhesive material layer, a heat dissipation sheet, an encapsulation material layer, a packaging circuit, and a packaging circuit protection layer protecting the packaging circuit, wherein a back surface of the chip is mounted at a chip mounting region of the heat dissipation sheet via the adhesive material layer; a front surface of the chip is covered by a temporary protection material; the encapsulation material layer is formed by making an encapsulation material flow into and fill a gap between the temporary protection material and the heat dissipation sheet and/or cover a side of the heat dissipation sheet opposite to a side thereof mounted with the chip, and then removing the temporary protection material, thus the encapsulation material layer covers the chip, the adhesive material layer, and the heat dissipation sheet; and the packaging circuit is formed by being grown on the front surface of the chip, the encapsulation material, and the heat dissipation sheet.

Optionally, in the above fan-out type package, the heat dissipation sheet has hollowed-out holes that are hollowed out in a thickness direction of the fan-out type package, and the hollowed-out hole is a channel for the encapsulation material constituting the encapsulation material layer to flow therethrough.

Optionally, in the above fan-out type package, in the thickness direction of the fan-out type package, a surface of the chip mounting region is located in a same horizontal plane as other regions of the heat dissipation sheet.

Optionally, in the above fan-out type package, in the thickness direction of the fan-out type package, a surface of the chip mounting region is higher than surfaces of other regions of the heat dissipation sheet.

Optionally, in the above fan-out type package, in the thickness direction of the fan-out type package, a surface of the chip mounting region is lower than surfaces of other regions of the heat dissipation sheet.

Optionally, in the above fan-out type package, a projection structure is provided on the heat dissipation sheet, and in the thickness direction of the fan-out type package, a surface of the projection structure is higher than the surface of the chip mounting region.

Optionally, in the above fan-out type package, in the thickness direction of the fan-out type package, the front surface of the chip is higher than a part of the heat dissipation sheet other than the chip mounting region, and the front surface of the chip is exposed from the encapsulation material layer in a manner of being located in a same plane as an upper surface of the encapsulation material layer.

Optionally, in the above fan-out type package, in the thickness direction of the fan-out type package, the front surface of the chip is located in a same plane as an upper surface of the projection structure of the heat dissipation sheet, and the front surface of the chip and the upper surface of the projection structure of the heat dissipation sheet are exposed from the encapsulation material layer in a manner of being located in a same plane as an upper surface of the encapsulation material layer, and the packaging circuit is formed by being directly grown on the front surface of the chip, the upper surface of the encapsulation material layer, and the upper surface of the projection structure of the heat dissipation sheet.

Optionally, in the above fan-out type package, the encapsulation material layer is provided with through holes in the thickness direction, with the through holes vertically running from the upper surface of the encapsulation material layer to an upper surface of a part of the heat dissipation sheet connected to the chip mounting region, and the through holes are channels for an electrically conducting material forming the packaging circuit to flow therethrough.

Optionally, in the above fan-out type package, the temporary protection material consists of peelable glue and a temporary carrying sheet.

Optionally, in the above fan-out type package, two surfaces of the heat dissipation sheet are each mounted with a chip.

Optionally, in the above fan-out type package, the adhesive material is an electrically conducting material.

Optionally, in the above fan-out type package, the adhesive material is an insulating material.

Optionally, in the above fan-out type package, the adhesive material has thermal conductivity.

The present disclosure provides a preparation method of the fan-out type package, including: a step of preparing a chip, in which a plurality of chips having the same or different functions are prepared; a step of preparing a heat dissipation sheet, in which a chip mounting region for mounting the chip and hollowed-out holes that are hollowed out in a thickness direction of the heat dissipation sheet are formed on the heat dissipation sheet; a step of mounting the chip, in which a back surface of the chip is mount through an adhesive material in the chip mounting region of the heat dissipation sheet; an encapsulating step, in which the front surface of the chip is fixed with a temporary protection material, an encapsulation material is made to flow into and fill a gap between the temporary protection material and the heat dissipation sheet and/or cover a side of the heat dissipation sheet opposite to a side thereof mounted with the chip, and the temporary protection material is removed, to thus form the encapsulation material layer covering the chip, the heat dissipation sheet, and the adhesive material; a step of preparing a packaging circuit, in which an electrically conducting material is made to grow on the front surface of the chip, the heat dissipation sheet, and the encapsulation material to form a packaging circuit layer; a step of preparing a packaging circuit protection layer and a bonding pad, in which the packaging circuit protection layer protecting the packaging circuit is produced on the packaging circuit, and the bonding pad of the package is formed on the packaging circuit protection layer; and a step of performing cutting to obtain a device, in which a single packaged device is formed by cutting.

Optionally, in the above preparation method of the fan-out type package, in a thickness direction of the fan-out type package, a front surface of the chip mounted in the chip mounting region in the mounting step is higher than an upper surface of a part of the heat dissipation sheet other than the chip mounting region, in an encapsulation structural body formed through the encapsulating step, the front surface of the chip is exposed from the encapsulation material layer in a manner of being located in a same plane as the upper surface of the encapsulation material layer, and the upper surface of the part of the heat dissipation sheet other than the chip mounting region is covered by the encapsulation material layer, and in the step of preparing a packaging circuit, through holes are formed on the encapsulation material layer in the thickness direction, with the through holes vertically running from the upper surface of the encapsulation material layer to the upper surface of the part of the heat dissipation sheet connected to the chip mounting region, and an electrically conducting material forming the packaging circuit flows in the through holes to reach the upper surface of the part of the heat dissipation sheet connected to the chip mounting region.

Optionally, in the above preparation method of fan-out type package, in the step of preparing a heat dissipation sheet, a projection structure is formed on the heat dissipation sheet, and in the thickness direction of the fan-out type package, a surface of the projection structure is higher than a surface of the chip mounting region, in the thickness direction of the fan-out type package, the front surface of the chip mounted in the chip mounting region through the mounting step is located in a same plane as the upper surface of the projection structure of the heat dissipation sheet, in an encapsulation structural body formed through the encapsulating step, the front surface of the chip is exposed from the encapsulation material layer in a manner of being located in a same plane as the upper surface of the encapsulation material layer, and the upper surface of the projection structure of the heat dissipation sheet is exposed from the encapsulation material layer in a manner of being located in a same plane as the upper surface of the encapsulation material layer, and in the step of preparing a packaging circuit, the packaging circuit is formed by being directly grown on the front surface of the chip, the projection structure of the heat dissipation sheet exposed from the encapsulation material layer, and the encapsulation material layer.

Optionally, in the above preparation method of the fan-out type package, in the step of preparing a heat dissipation sheet, in the thickness direction, thickness of the chip mounting region of the heat dissipation sheet is reduced, so that the chip mounting region is lower than upper surfaces of other parts of the heat dissipation sheet.

Optionally, in the above preparation method of the fan-out type package, in the encapsulating step, the temporary protection material is a temporary carrier, and the front surface of the chip is fixed, through bonding, with the temporary carrier.

### BRIEF DESCRIPTION OF THE DRAWINGS

In order to more clearly illustrate technical solutions of the present disclosure, accompanying drawings are introduced briefly below. It should be understood that the accompanying drawings merely show some embodiments of the present disclosure, therefore, they should not be considered as limiting to the scope, and those ordinarily skilled in the art still could derive other relevant drawings according to these accompanying drawings, without using any creative efforts.

FIGS. 1A˜1F are partial sectional views of a fan-out type package of the present disclosure;

FIG. 2 is a flow chart of a preparation method of the fan-out type package of the present disclosure;

FIG. 3 is a schematic diagram illustrating a step of preparing a chip;

FIGS. 4A˜4C are schematic diagrams illustrating steps of preparing a heat dissipation sheet;

FIGS. 5A˜5D are schematic diagrams illustrating a chip mounting step;

FIGS. 6A˜6L are schematic diagrams illustrating an encapsulation step;

FIGS. 7A and 7B are schematic diagrams illustrating a step of forming an electrically conducting material layer;

FIG. 8 is a schematic diagram illustrating the fan-out type package prepared by a preparation method of fan-out type package; and

FIG. 9 is a schematic diagram illustrating a single device obtained from a fan-out type package structural body shown in FIG. 8.

### DETAILED DESCRIPTION OF THE EMBODIMENTS

In order to make objectives, technical solutions, and advantages of the embodiments of the present disclosure clearer, the technical solutions in the embodiments of the present disclosure will be described clearly and completely below in conjunction with the accompanying drawings in the embodiments of the present disclosure, where the embodiments described are some but not all possible embodiments within the scope of the present disclosure. Generally, components in the embodiments of the present disclosure, as described and shown in the accompanying drawings herein, may be arranged and designed in various different configurations.

Therefore, the detailed description below of the embodiments of the present disclosure provided in the accompanying drawings is not intended to limit the scope of the present disclosure claimed, but merely illustrates chosen embodiments of the present disclosure. All of other embodiments obtained by those ordinarily skilled in the art based on the embodiments in the present disclosure without using creative efforts shall fall within the scope of protection of the present disclosure.

It should be noted that similar reference signs and letters represent similar items in the following accompanying drawings, therefore, once a certain item is defined in one accompanying drawing, it is not needed to be further defined or explained in subsequent accompanying drawings.

In the description of the present disclosure, it should be indicated that orientation or positional relationships indicated by terms such as “center”, “upper”, “lower”, “left”, “right”, “vertical”, “horizontal”, “inner”, and “outer” are based on orientation or positional relationships as shown in the accompanying drawings, or orientation or positional relationships of a product of the present disclosure conventionally placed when in use, merely for facilitating describing the present disclosure and simplifying the description, rather than indicating or suggesting that related devices or elements have to be in the specific orientation, or configured or operated in a specific orientation, therefore, they should not be construed as limiting the present disclosure. Besides, terms such as “first”, “second”, and “third” are merely for distinctive description, but should not be construed as indicating or implying importance in the relativity.

Moreover, the terms “horizontal”, “vertical”, “overhanging”, and the like do not mean that the parts are required to be absolutely horizontal or overhanging, but may be slightly inclined. For example, by “horizontal” it merely means that a structure is more horizontal in comparison with “vertical”, rather than being completely horizontal, while the structure may be slightly inclined.

Moreover, terms “including”, “containing” or any other derivatives thereof are intended to be non-exclusive, thus a process, method, article or device including a series of elements not only include those elements, but also include other elements that are not listed definitely, or further include elements inherent to such process, method, article or device. Without more restrictions, an element defined with wordings “including a . . . ” does not exclude presence of other same elements in the process, method, article or device including said element.

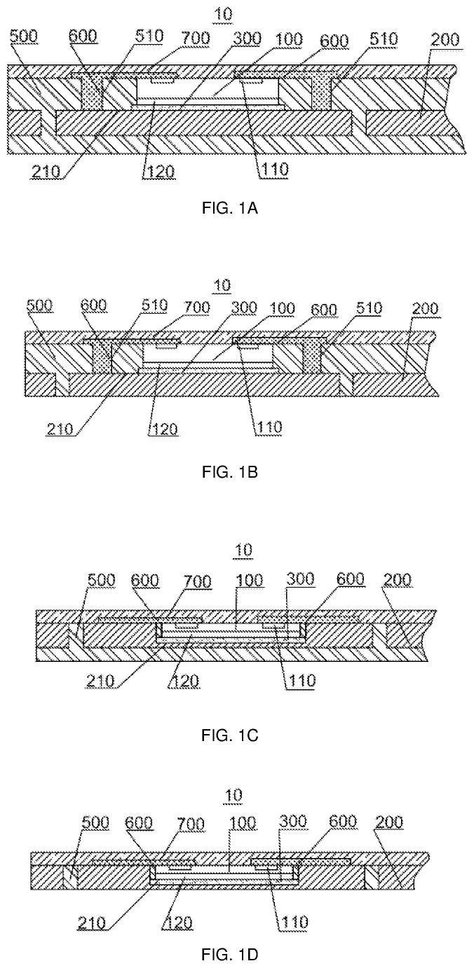

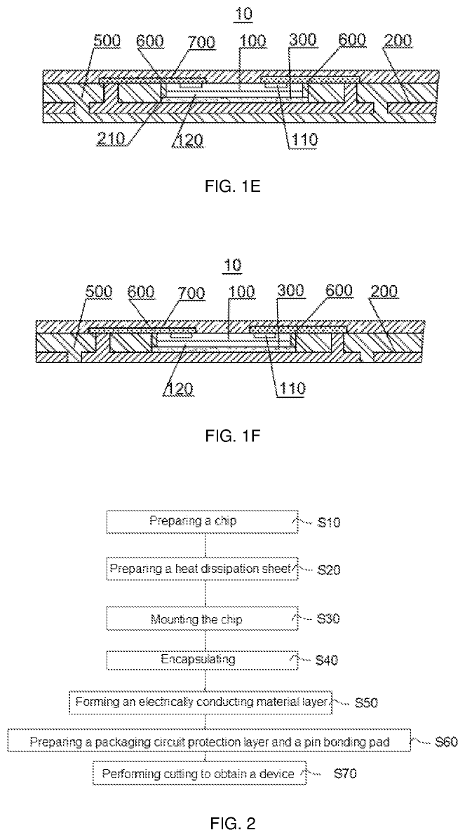

First, the fan-out type package provided in the present disclosure is described with reference to FIGS. 1A˜1F. FIGS. 1A˜1F are partial sectional views illustrating the fan-out type package 10, and only one chip 100 is shown in the drawings, but the chip 100 is not limited to one chip, and two or more chips 100 having the same or different functions are also possible.

The fan-out type package 10 includes one or two or more chips 100 having the same or different functions, an adhesive material layer 300, a heat dissipation sheet 200, an encapsulation material layer 500, an electrically conducting material layer 600 as a packaging circuit, a packaging circuit protection layer 700 protecting the packaging circuit, and packaging pin(s) formed on the packaging circuit protection layer 700 and not shown in the drawings.

In FIGS. 1A˜1F, a front surface of the chip 100, i.e., the upper surface in FIGS. 1A˜1F, is a functional surface, and is formed with circuit(s) and/or device(s), or the like, and has pins 110. In FIGS. 1A˜1F, only two pins are shown, but it is not limited thereto, while there may be two or more pins. A metal layer 120 as the electrically conducting layer is deposited on the back surface of the chip 100, and the metal layer 120 may also have thermal conductivity. Optionally, it is also possible that the back surface of the chip 100 is not provided with the metal layer 120, and illustration is omitted herein.

The adhesive material layer 300 may be a material having good thermal conductivity, may have electrical conductivity, or may not have electrical conductivity, for example, the adhesive material layer may be a conductive silver adhesive, a metal or an alloy material and so on.

The heat dissipation sheet 200 may be a metal plate or a ceramic plate, or may be a plate taking resin, metal or ceramic as a substrate and covered with copper on a surface, or may be a variety of composite materials with high thermal conductance, having thermal conductivity and electrical conductivity. The heat dissipation sheet 200 has holes (hollowed-out holes) 220 that are hollowed out in a thickness direction and a chip mounting region 210, and the holes 220 are used as channels for an encapsulation material constituting the encapsulation material layer 500 to flow therethrough. As viewed from above, the chip mounting region 210 has a larger area than the chip 100, so as to facilitate alignment of the chip 100. As shown in FIGS. 1A and 1B, an upper surface of the chip mounting region 210 may be located in the same plane as upper surfaces of other regions of the heat dissipation sheet 200. It also may be as shown in FIGS. 1C and 1D that the upper surface of the chip mounting region 210 is lower than upper surfaces of other regions of the heat dissipation sheet 200. It also may be as shown in FIGS. 1E and 1F that the upper surface of the chip mounting region 210 is lower than an upper surface of a specified region (also referred to as a projection structure) of the heat dissipation sheet 200. The projection structure is electrically connected to the pins of the chip 100 through the electrically conducting material layer 600. In addition, it is also possible that the upper surface of the chip mounting region is higher than the upper surface of a region of the heat dissipation sheet other than the chip mounting region, which is not illustrated herein.

The encapsulation material layer 500 covers the heat dissipation sheet 200, the chip 100, and the adhesive material layer 300, and the front surface of the chip 100 is exposed from the encapsulation material layer 500 in a manner of being located in the same plane as an upper surface of the encapsulation material layer 500, and the encapsulation material layer 500 may completely cover the heat dissipation sheet 200, or the surface of the heat dissipation sheet 200 may be exposed from the encapsulation material layer 500 in a manner of being located in the same plane as the surface of the encapsulation material layer 500. The encapsulation material of the encapsulation material layer 500 may be made of a known material such as a polymer or an inorganic insulating material, which is not particularly limited herein. For the encapsulation material layer 500, as in a preparation method of the fan-out type package described later, in a situation that the front surface of the chip 100 is bonded with a temporary protection material such as a temporary carrier or adhered with a temporary protection material such as a temporary carrier, the encapsulation material is enabled to flow into and fill a gap between the heat dissipation sheet 200 and the temporary protection material such as the temporary carrier, and after the encapsulation material is cured, the bonding between the front surface of the chip 100 and the temporary protection material such as the temporary carrier is released, or the temporary protection material such as the adhered temporary carrier is removed, thus forming the encapsulation material layer 500.

The electrically conducting material layer 600 makes a specified part of the chip 100, such as a predetermined pin, electrically connected with the heat dissipation sheet 200. It is also possible that the electrically conducting material layer 600 does not electrically connect the chip 100 and the heat dissipation sheet 200, but enables the chip to be electrically connected to other elements through pin(s) on a packaged device formed by cutting the fan-out type package. As to the material forming the electrically conducting material layer, electrically conducting metal materials such as copper and aluminum can be listed, which is not particularly limited herein. The thickness of the electrically conducting material layer 600 is not particularly limited, and can be any thickness as long as electrically connection between the specified part of the chip 100 and the heat dissipation sheet 200 can be achieved. As viewed from above, the shape of the electrically conducting material layer 600 is any as long as it can completely cover the specified part, for example, the pin(s), of the chip 100, and the electrically conducting material layer may be designed in different shapes and different dimensions according to use conditions, which is not particularly limited herein. The electrically conducting material layer 600 protrudes from the upper surface, i.e., the front surface, of the chip 100.

The packaging circuit protection layer 700 is formed on the electrically conducting material layer 600, to protect the electrically conducting material layer 600 from external forces and the like, and a known material such as a polymer or an inorganic insulating material can be used, which is not particularly limited herein. The thickness of the packaging circuit protection layer 700 is not particularly limited, and can be any thickness as long as the electrically conducting material layer 600 can be covered.

Hereinafter, the structure of the fan-out type package 10 is described specifically with reference to FIGS. 1A˜1F.

FIG. 1A shows a fan-out type package (hereinafter also simply referred to as package) 10 with the heat dissipation sheet 200 being completely covered by the encapsulation material layer 500. An upper surface (hereinafter, the “upper surface” refers to a surface located above in FIGS. 1A˜1C, and other members are also in the same case) of the chip mounting region 210 of the heat dissipation sheet 200 is located in the same plane as upper surfaces of other regions. The chip 100 is adhesively fixed to the chip mounting region 210 via the adhesive material layer 300, the encapsulation material layer 500 completely covers the heat dissipation sheet 200, and the front surface of the chip 100 is exposed from the encapsulation material layer 500 in a manner of being located in the same plane as the upper surface of the encapsulation material layer 500. Interconnection holes 510 are formed in the encapsulation material layer 500, running from the upper surface of the encapsulation material layer to the upper surface of the heat dissipation sheet 200, and the electrically conducting material layer 600 is also formed in the interconnection holes 510, thus the electrically conducting material layer 600 electrically connects predetermined pin(s) of the chip 100 to the heat dissipation sheet 200. The packaging circuit protection layer 700 that protects the electrically conducting material layer 600 from external forces and the like and packaging pins not shown in the drawings are formed on the electrically conducting material layer 600. As the heat dissipation sheet has electrical conductivity, the interconnection between pins of different chips can be realized through the electrically conducting material layers and the heat dissipation sheets.

Optionally, in the package shown in FIG. 1A, the upper surface of the chip mounting region 210 on the heat dissipation sheet 200 may also be lower than or higher than upper surfaces of other regions, the front surface of the chip 100 fixed and adhered to the chip mounting region 210 via the adhesive material layer 300 is higher than the upper surface of the chip mounting region 210, and the encapsulation material layer 500 completely covers the heat dissipation sheet 200, which is not illustrated herein.

FIG. 1B shows the package 10 in which a lower surface (hereinafter, the “lower surface” refers to a surface located below in FIGS. 1A˜1C, and other members are also in the same case) of the heat dissipation sheet 200 is exposed from the encapsulation material layer 500 in a manner of being located in the same plane as the lower surface of the encapsulation material layer 500. The upper surface of the chip mounting region 210 on the heat dissipation sheet 200 is located in the same plane as upper surfaces of other regions. The chip 100 is adhesively fixed to the chip mounting region 210 via the adhesive material layer 300, the lower surface of the heat dissipation sheet 200 is exposed from the encapsulation material layer 500 in a manner of being located in the same plane as the lower surface of the encapsulation material layer 500, and the front surface of the chip 100 is exposed from the encapsulation material layer 500 in a manner of being located in the same plane as the upper surface of the encapsulation material layer 500. On the encapsulation material layer 500, the interconnection holes 510 are formed from the upper surface of the encapsulation material layer to the upper surface of the heat dissipation sheet 200, and the electrically conducting material layer 600 is also formed in the interconnection holes 510, thus the electrically conducting material layer 600 electrically connects predetermined pin(s) of the chip 100 to the heat dissipation sheet 200. The packaging circuit protection layer 700 that protects the electrically conducting material layer 600 from external forces and the like and packaging pins not shown in the drawings are formed on the electrically conducting material layer 600. As the heat dissipation sheet has electrical conductivity, the interconnection between pins of different chips can be realized through the electrically conducting material layers and the heat dissipation sheets.

Optionally, in the package shown in FIG. 1B, the upper surface of the chip mounting region 210 on the heat dissipation sheet 200 may also be lower than or higher than upper surfaces of other regions, the front surface of the chip 100 fixed and adhered to the chip mounting region 210 via the adhesive material layer 300 is higher than the upper surface of the chip mounting region 210, and the upper surface of the heat dissipation sheet 200 is covered by the encapsulation material layer 500, which is not illustrated herein.

FIG. 1C shows the package 10 in which the upper surface of the heat dissipation sheet 200 is exposed from the encapsulation material layer 500 in a manner of being located in the same plane as the upper surface of the encapsulation material layer 500. The upper surface of the chip mounting region 210 of the heat dissipation sheet 200 is lower than upper surfaces of other regions. The chip 100 is adhesively fixed to the chip mounting region 210 via the adhesive material layer 300, and the front surface of the chip 100 and the upper surfaces of the other regions of the heat dissipation sheet 200 are located in the same plane, the upper surface of the heat dissipation sheet 200 and the front surface of the chip 100 are exposed from the encapsulation material layer 500 in a manner of being located in the same plane as the upper surface of the encapsulation material layer 500, and the lower surface of the heat dissipation sheet 200 is covered by the encapsulation material layer 500. Different from the packages shown in FIG. 1A and FIG. 1B, there is no interconnection hole 510 formed in the encapsulation material layer 500, and the electrically conducting material layer 600 is directly formed on the upper surface of the heat dissipation sheet 200, the upper surface of the encapsulation material layer 500, and the front surface of the chip 100, thus the electrically conducting material layer 600 electrically connects predetermined pin(s) of the chip 100 with the heat dissipation sheet 200. The packaging circuit protection layer 700 that protects the electrically conducting material layer 600 from external forces and the like and packaging pins not shown in the drawings are formed on the electrically conducting material layer 600. As the heat dissipation sheet has electrical conductivity, the interconnection between pins of different chips can be realized through the electrically conducting material layers and the heat dissipation sheets.

FIG. 1D shows the package 10 in which the upper surface and the lower surface of the heat dissipation sheet 200 are exposed from the encapsulation material layer 500 in a manner of being located in the same plane as the upper surface and the lower surface of the encapsulation material layer 500. The upper surface of the chip mounting region 210 on the heat dissipation sheet 200 is lower than the upper surfaces of other regions, the chip 100 is adhesively fixed to the chip mounting region 210 via the adhesive material layer 300, the front surface of the chip 100 is located in the same plane as the upper surfaces of the other regions of the heat dissipation sheet 200, and the upper surface of the heat dissipation sheet 200 and the front surface of the chip 100 are exposed from the encapsulation material layer 500 in a manner of being located in the same plane as the upper surface of the encapsulation material layer 500. Different from the packages shown in FIG. 1A and FIG. 1B, there is no interconnection hole 510 formed in the encapsulation material layer 500, the electrically conducting material layer 600 is directly formed on the upper surface of the heat dissipation sheet 200, the upper surface of the encapsulation material layer 500, and the front surface of the chip 100, thus the electrically conducting material layer 600 electrically connects predetermined pin(s) of the chip 100 with the heat dissipation sheet 200. The packaging circuit protection layer 700 that protects the electrically conducting material layer 600 from external forces and the like and packaging pins not shown in the drawings are formed on the electrically conducting material layer 600. As the heat dissipation sheet has electrical conductivity, the interconnection between pins of different chips can be realized through the electrically conducting material layers and the heat dissipation sheets.

FIG. 1E shows the package 10 in which the upper surface of the projection structure of the heat dissipation sheet 200 is higher than the other regions of the heat dissipation sheet, and the projection structure is exposed from the encapsulation material layer 500 in a manner of being located in the same plane as the upper surface of the encapsulation material layer 500. The chip mounting region 210 on the heat dissipation sheet 200 is located in the same plane as the upper surfaces of regions other than the projection structure, the chip 100 is adhesively fixed to the chip mounting region 210 via the adhesive material layer 300, the front surface of the chip 100 is located in the same plane as the upper surface of the projection structure, the upper surface of the projection structure and the front surface of the chip 100 are exposed from the encapsulation material layer 500 in a manner of being located in the same plane as the upper surface of the encapsulation material layer 500, and the lower surface of the heat dissipation sheet 200 is covered by the encapsulation material layer 500. Different from the packages shown in FIG. 1A and FIG. 1B, there is no interconnection hole 510 formed in the encapsulation material layer 500, and the electrically conducting material layer 600 is directly formed on the upper surface of the projection structure of the heat dissipation sheet 200, the upper surface of the encapsulation material layer 500, and the front surface of the chip 100, thus the electrically conducting material layer 600 electrically connects predetermined pin(s) of the chip 100 with the heat dissipation sheet 200. The packaging circuit protection layer 700 that protects the electrically conducting material layer 600 from external forces and the like and packaging pins not shown in the drawings are formed on the electrically conducting material layer 600. As the heat dissipation sheet has electrical conductivity, the interconnection between pins of different chips can be realized through the electrically conducting material layers and the heat dissipation sheets.

FIG. 1F shows the package 10 in which the upper surface of the projection structure of the heat dissipation sheet 200 is higher than the other regions of the heat dissipation sheet, and the projection structure is exposed from the encapsulation material layer 500 in a manner of being located in the same plane as the upper surface of the encapsulation material layer 500 and the lower surface of the heat dissipation sheet 200 is exposed from the encapsulation material layer 500 in a manner of being located in the same plane as the lower surface of the encapsulation material layer 500. The chip mounting region 210 on the heat dissipation sheet 200 is located in the same plane as upper surfaces of regions other than the projection structure. The chip 100 is adhesively fixed to the chip mounting region 210 via the adhesive material layer 300, the front surface of the chip and the upper surface of the projection structure are located in the same plane, and the upper surface of the projection structure and the front surface of the chip 100 are exposed from the encapsulation material layer 500 in a manner of being located in the same plane as the upper surface of the encapsulation material layer 500. Different from the packages shown in FIG. 1A and FIG. 1B, there is no interconnection hole 510 formed in the encapsulation material layer 500, and the electrically conducting material layer 600 is directly formed on the upper surface of the projection structure of the heat dissipation sheet 200, the upper surface of the encapsulation material layer 500, and the front surface of the chip 100, thus the electrically conducting material layer 600 electrically connects a predetermined pin(s) of the chip 100 with the heat dissipation sheet 200. The packaging circuit protection layer 700 that protects the electrically conducting material layer 600 from external forces and the like and packaging pins not shown in the drawings are formed on the electrically conducting material layer 600. As the heat dissipation sheet has electrical conductivity, the interconnection between pins of different chips can be realized through the electrically conducting material layers and the heat dissipation sheets.

In addition, through combination, in one package, there may be only one structure of FIG. 1A˜FIG. 1F, or there may be two or more structures of FIG. 1A˜FIG. 1F, which is not particularly limited herein.

For the above fan-out type package, the electrically conducting material layer is formed through in-situ growth of an electrically conducting material, enabling the electrical connection between a specified part of the chip and the heat dissipation sheet, thus the interconnection between pins of different chips is realized, and a bonding pad having a dimension far larger than that of the pin of the chip and protruding from the front surface of the chip is directly formed on the pin of the chip, so that the thickness of the pin is greatly increased, an interconnection line is short, an effective electrically conducting area is large, and a larger current may be carried, then the interconnection reliability is high. In addition, the heat generated by the chip may be dissipated from the front surface, the back surface, and a side surface simultaneously through the heat dissipation sheet and the bonding pad, significantly improving the heat dissipation performance. In addition, the package has small thermal resistance, may significantly reduce an operation temperature of devices, improve the reliability of packaged devices, may improve the operation power and reduce the power consumption of devices, and may integrate chips with a high power density. The dimension and thickness of the package can also be reduced. The method for manufacturing the package is simple, and the cost can be reduced.

In the above, the case where the chip is mounted on one side of the heat dissipation sheet is described, and it is also possible that the upper surface and lower surface of the heat dissipation sheet are both mounted with a chip, and the illustration is omitted herein.

Hereinafter, a preparation method of the fan-out type package of the present disclosure is described with reference to FIG. 2˜FIG. 9. The method includes step S10˜step S70.

Step S10, preparing a chip 100.

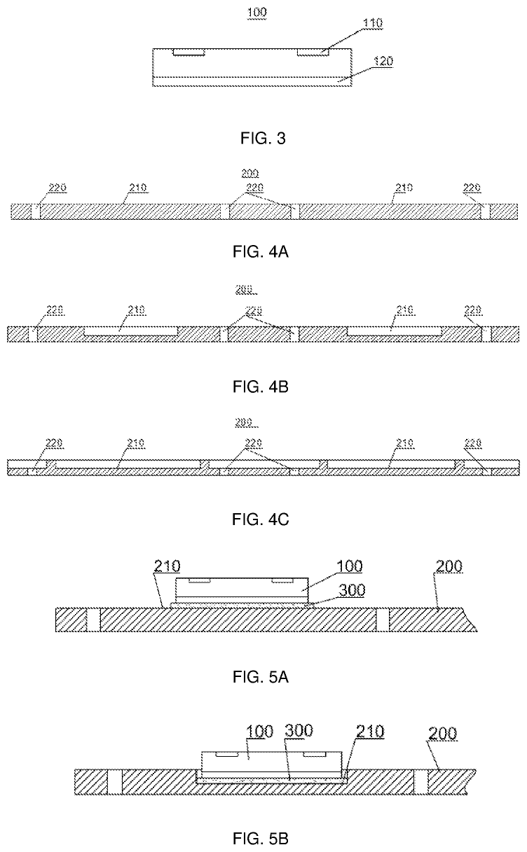

In order to be adapted to the development of electronic products, the chip 100 adopts a chip with a high power density and a reduced thickness, and the preparation of the chip may adopt a known preparation method, of which the description is omitted herein. A prepared chip 100 is shown in FIG. 3. A front surface of the chip 100 is a functional surface, and is formed with circuit(s) and/or device(s), or the like, and has pins 110. In FIG. 3, only two pins are shown, but it is not limited thereto, while there may be two or more pins. A metal layer 120 as an electrically conducting layer is deposited on a back surface of the chip 100, and the metal layer 120 may also have thermal conductivity. Optionally, it is also possible that the back surface of the chip 100 is not provided with the metal layer 120, and illustration is omitted herein.

Step S20, preparing a heat dissipation sheet.

FIGS. 4A˜4C are schematic diagrams illustrating a heat dissipation sheet 200 prepared through steps of preparing a heat dissipation sheet.

A blank material of the heat dissipation sheet may be a metal plate or a ceramic plate, or may be a plate taking resin, metal or ceramic as a substrate and covered with copper on a surface, or may be a variety of composite materials with high thermal conductance. The blank material of the heat dissipation sheet has thermal conductivity, and may also have electrical conductivity.

By using such blank materials of the heat dissipation sheet, hollowed-out through holes 220 are formed by removing unneeded parts of the blank material of the heat dissipation sheet according to pattern design through mechanical processing or etching and so on by a machining device such as a laser device, or an etching device such as a chemical etching device, thus, the heat dissipation sheet 200 having the through holes 220 and the chip mounting region 210 is fabricated, that is, as shown in FIG. 4A, the through holes 220 are formed, and the upper surface of the chip mounting region 210 and the upper surfaces of other regions are located in the same plane. As viewed from above, the chip mounting region 210 has a larger area than the chip 100 to be mounted, so as to facilitate alignment of the chip 100.

In addition, the chip mounting region 210 also may be thinned, through one or more of laser punching or chemical etching and so on, by a laser device or a chemical etching device, so that an upper surface of this region is lower than upper surfaces of other portions of the heat dissipation sheet 200, that is, as shown in FIG. 4B, the through holes 220 are formed, and the upper surface of the chip mounting region 210 is lower than the upper surfaces of other regions. Besides, parts other than the chip mounting region are thinned, through one or more of laser punching or chemical etching and so on, by a laser device or a chemical etching device, so that an upper surface of the chip mounting region is higher than the upper surfaces of other parts of the heat dissipation sheet, the through holes are formed, and the upper surface of the chip mounting region is higher than the upper surfaces of other regions, of which the illustration is omitted herein.

In addition, parts of the heat dissipation sheet 200 other than the projection structure also may be thinned, through one or more of mechanical punching such as laser punching or chemical etching, by a laser device or a chemical etching device, so that the upper surface of the projection structure is higher than the upper surfaces of other parts, including the chip mounting region 210, of the heat dissipation sheet 200, that is, as shown in FIG. 4C, the through holes 220 are formed, and the projection structure of the heat dissipation sheet 200 is higher than upper surfaces of other parts, including the chip mounting region 210, of the heat dissipation sheet 200.

Moreover, the height of the projection structure of the heat dissipation sheet 200 is a height, such that in cases where the chip 100 is mounted in the chip mounting region 210 by the chip mounting step described later, the upper surface of the projection structure is located in the same plane as the upper surface of the mounted chip 100.

In a case of laser punching, the blank material of the heat dissipation sheet may be fixed to a chuck of a laser punching machine or the like, and the hollowed-out holes are formed at a specified position on the blank material of the heat dissipation sheet by laser light, thereby forming the through holes 220. The thinning of the chip mounting region and parts other than the projection structure are also similar, and a part of the heat dissipation sheet in the thickness direction is removed by laser light to realize thinning.

In a case of thinning by the chemical etching, the blank material of the heat dissipation sheet is etched by an etching device with an etching solution, to remove partial region of the blank material of the heat dissipation sheet to make this part hollowed, and reduce the thickness of partial region of the heat dissipation sheet to form a thinned region. Specifically, a main component of the etching solution is potassium hydroxide, and other compounds such as accelerator may also be contained. The blank material of the heat dissipation sheet is immersed in an etching tank accommodating the above chemical etching solution, to etch the blank material of the heat dissipation sheet, for example, to etch with the help of a mask, thereby a hollowed-out hole and a region with a reduced thickness are formed at specified positions on the blank material of the heat dissipation sheet. In addition, during the chemical etching, the etching solution may be stirred or heated, thereby increasing the etching speed and shortening the etching time.

Forming the through holes 220 in the heat dissipating plate 200 can increase a heat dissipation area of the heat dissipation sheet 200.

Besides, a compress casting device or a mold casting device also may be adopted to form the heat dissipation sheet having through hole and a thinned structure, that is, the heat dissipation sheet with a structure shown in FIGS. 4A˜4C, through compress casting or mold casting.

Step S30, mounting the chip on the heat dissipation sheet.

An adhesive material having electrical conductivity and good thermal conductivity is used to mount the back surface of the chip 100 to the chip mounting region 210, and the adhesive material also may be an insulating but thermally conducting material.

The thermally conducting and insulating adhesive material only needs to use general adhesives, and since they are generally known in the art, no specific description is made. General adhesives are insulating, and the adhesives may have certain electrical conductivity by adding silver powder, carbon black or the like, so the electrically conducting and thermally conducting adhesive material is an adhesive material formed by adding silver powder, carbon black or the like to a general adhesive.

Specifically, in a chip packaging machine, the heat dissipation sheet 200 is fixed on a sucker or the like, the adhesive material is coated on the chip mounting region 210 of the heat dissipation sheet 200 by an adhesive coating device, then, the chip 100 is picked up by a mechanical hand or the like and placed on the adhesive material in such a manner that the back surface of the chip 100 faces the heat dissipation sheet 200, the adhesive material layer 300 is formed through curing of the adhesive material, and the back surface of the chip 100 is adhesively fixed to the chip mounting region 210 via the adhesive material layer 300.

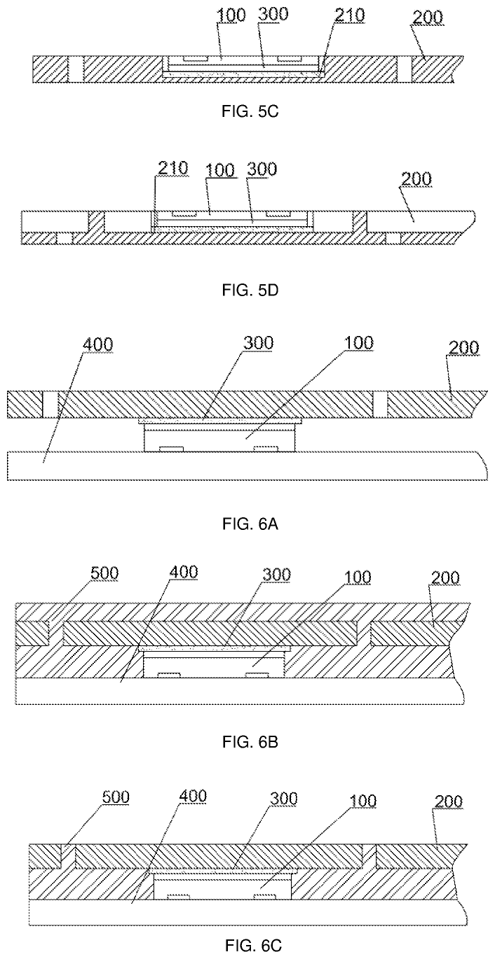

FIGS. 5A˜5D show a structural body in which the chip 100 is mounted on the upper surface of the chip mounting region 210 by the chip mounting step. In the structural body shown in FIG. 5A, the upper surface of the chip mounting region 210 and the upper surfaces of other regions of the heat dissipation sheet 200 are located in the same plane, the front surface of the chip 100 is higher than the upper surfaces of other regions of the heat dissipation sheet 200. In the structural body shown in FIG. 5B, the upper surface of the chip mounting region 210 is lower than the upper surfaces of other regions of the heat dissipation sheet 200, and the front surface of the chip 100 is higher than the upper surfaces of other regions of the heat dissipation sheet 200. In the structural body shown in FIG. 5C, the upper surface of the chip mounting region 210 is lower than the upper surface of other regions of the heat dissipation sheet 200, and the front surface of the chip 100 and the upper surfaces of other regions of the heat dissipation sheet 200 are located in the same plane. In the structural body shown in FIG. 5D, the upper surface of the projection structure of the heat dissipation sheet 200 is higher than the upper surfaces of other regions including the chip mounting region 210, the front surface of the chip 100 and the upper surface of the projection structure of the heat dissipation sheet 200 are located in the same plane, and the projection structure of the heat dissipation sheet 200 is a region electrically connected to the chip 100 in a step described later.

Herein, only the case where the chip is mounted on the upper surface of the heat dissipation sheet is shown, and it is also possible that both upper surface and lower surface of the heat dissipation sheet are mounted with a chip.

Step S40, encapsulating the heat dissipation sheet with the chip.

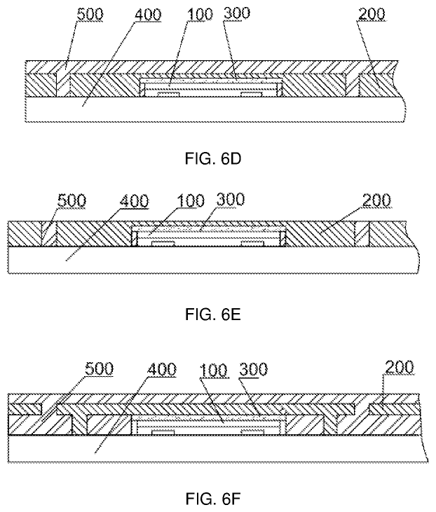

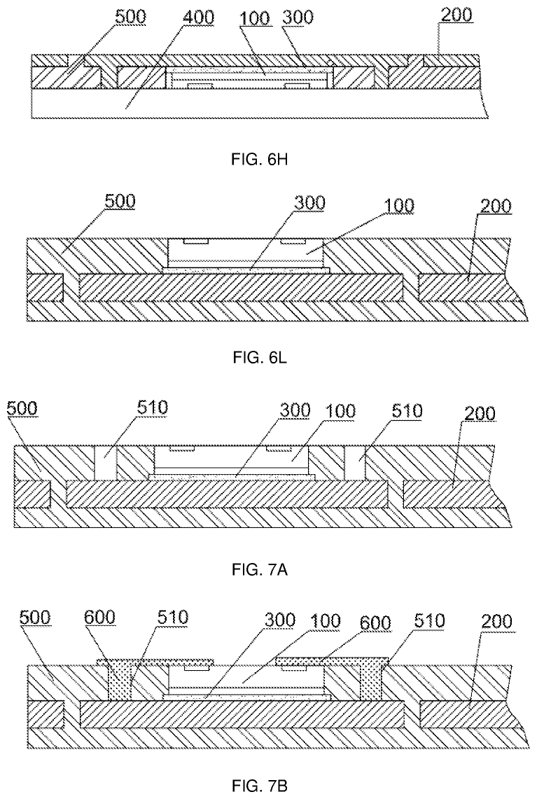

As shown in FIG. 6A, first, the heat dissipation sheet 200 adhered with the chip 100 is turned over to allow the front surface of the chip 100 to be bonded to a temporary carrier 400, and then, as shown in FIGS. 6B˜6H, the chip 100 bonded with the temporary carrier 400, the adhesive material layer 300, and the heat dissipation sheet 200 are encapsulated with an encapsulation material, and further, as shown in FIG. 6L, the bonding between the temporary carrier 400 and the chip 100 is released. Herein, bonding means that the chip 100 and the temporary carrier 400, having undergone surface cleaning and activation treatment, are directly combined under a certain condition, and wafers are bonded into one piece by van der Waals force or molecular force and so on.

In addition, it is also possible that the bonding is not performed, but the chip is adhesively fixed to the temporary carrier 400 by the adhesive material, and the adhesive material used herein only needs to be a general adhesive material, therefore the description is omitted.

By a transfer mold device, a compress mold device, an inject mold device, a vacuum lamination device or the like that are generally known, in a state that the temporary carrier 400 is fixed on a fixing device such as a sucker of the mold device, a certain amount of encapsulation material is supplied from a material supply unit of the mold device to one side of the heat dissipation sheet 200, to cover the temporary carrier 400, the chip 100, the adhesive material layer 300, and the heat dissipation sheet 200, and then the encapsulation material is cured to form the encapsulation material layer 500. The encapsulation material may adopt a generally known material such as a polymer or an inorganic insulating material, which is not particularly limited herein.

The configuration of the encapsulation material layer 500 varies depending on the structural body formed by the chip 100, the heat dissipation sheet 200, and the adhesive material layer 300. FIGS. 6B and 6C show encapsulation structural bodies formed by encapsulating the structural body shown in FIG. 5A. In the encapsulation structural body shown in FIG. 6B, the encapsulation material layer 500 completely covers the heat dissipation sheet 200 and the adhesive material layer 300, the front surface of the chip 100 is exposed from the upper surface of the encapsulation material layer 500. In the encapsulation structural body shown in FIG. 6C, the encapsulation material layer 500 covers the upper surface of the heat dissipation sheet 200 and the adhesive material layer 300, the front surface of the chip 100 is exposed from the upper surface of the encapsulation material layer 500, and the lower surface of the heat dissipation sheet 200 is exposed from the lower surface of the encapsulation material layer 500. The structural body shown in FIG. 5B and the structural body shown in FIG. 5A are the same. Through the encapsulating step, it is possible to form an encapsulation structure in which the encapsulation material layer 500 completely covers the heat dissipation sheet 200 and the adhesive material layer 300, and the front surface of the chip 100 is exposed from the upper surface of the encapsulation material layer 500, and it is also possible to form an encapsulation structural body in which the encapsulation material layer 500 covers the upper surface of the heat dissipation sheet 200 and the adhesive material layer 300, and the front surface of the chip 100 is exposed from the upper surface of the encapsulation material layer 500 and the lower surface of the heat dissipation sheet 200 is exposed from the lower surface of the encapsulation material layer 500.

FIGS. 6D and 6E show encapsulation structural bodies formed by encapsulating the structural body shown in FIG. 5C. In the encapsulation structural body shown in FIG. 6D, the encapsulation material layer 500 covers the lower surface of the heat dissipation sheet 200 and the adhesive material layer 300, and the front surface of the chip 100 and the upper surface of the heat dissipation sheet 200 are exposed from the upper surface of the encapsulation material layer 500. In the encapsulation structural body shown in FIG. 6E, the encapsulation material layer 500 covers the adhesive material layer 300, and the front surface of the chip 100, the upper surface of the heat dissipation sheet 200, and the lower surface of the heat dissipation sheet 200 are exposed from the encapsulation material layer 500.

FIGS. 6F and 6H show encapsulation structural bodies formed by encapsulating the structural body shown in FIG. 5D. In the encapsulation structural body shown in FIG. 6F, the encapsulation material layer 500 covers upper surfaces of parts of the heat dissipation sheet 200 other than the chip mounting region and the projection structure, the lower surface of the heat dissipation sheet 200, and the adhesive material layer 300, and the front surface of the chip 100 and the upper surface of the projection structure of the heat dissipation sheet 200 are exposed from the upper surface of the encapsulation material layer 500. In the encapsulation structural body shown in FIG. 6E, the encapsulation material layer 500 covers upper surfaces of parts of the heat dissipation sheet 200 other than the chip mounting region and the projection structure and the adhesive material layer 300, and the front surface of the chip 100, the upper surface of the projection structure of the heat dissipation sheet 200, and the lower surface of the heat dissipation sheet 200 are exposed from the encapsulation material layer 500.

Next, the bonding between the temporary carrier and the chip 100 is released, or the temporary carrier and the adhesive material for bonding the temporary carrier and the chip are removed.

The temporary carrier 400 is only a temporary protection material that protects the chip 100 when forming the encapsulation material layer 500, therefore, after the encapsulation material layer 500 is formed, the temporary carrier 400 needs to be removed.

The bonding between the temporary carrier and the chip 100 may be released by applying an external force, alternatively, as a method for removing the temporary carrier adhered by an adhesive material, a generally known method may be used, for example, chemical etching, wherein the temporary carrier and the adhesive material are removed by an etching device with an etching solution, thus forming the structural body shown in FIG. 6L. FIG. 6L shows an encapsulation structural body corresponding to FIG. 6B. Encapsulation structural bodies corresponding to FIG. 6C and FIG. 6H are omitted herein.

Step S50, forming an electrically conducting material layer as a packaging circuit.

An electrically conducting material layer 600 electrically connecting predetermined pin(s) of the chip 100 with the heat dissipation sheet 200 is formed from an electrically conducting material through electroless plating, electroplating, silk-screen/steel-mesh printing and so on by an electroless plating device, an electroplating device, a silk-screen printing device or a steel-mesh printing device generally known in the art.

If it is the structural body shown in FIG. 6B and FIG. 6C, that is, the front surface of the chip 100 is exposed from the encapsulation material layer 500 and the upper surface of the heat dissipation sheet 200 is covered by the encapsulation material layer 500, first, as shown in FIG. 7, a plurality of interconnection holes 510 are formed on the encapsulation structural body formed through step 40, with the interconnection holes running from the upper surface of the encapsulation material layer 500 to the upper surface of a part of the heat dissipation sheet 200 connected to the chip mounting region 210, subsequently, the electrically conducting material layer 600 is formed in the interconnection holes 510, the encapsulation material layer 500, and a specified part of the front surface of the chip 100 through electroless plating, electroplating, silk-screen/steel-mesh printing by an electroless plating device, an electroplating device, a silk-screen printing device, or a steel-mesh printing device generally known in the art.

As for the formation of the interconnection holes, a laser device, a photoetching device, or a chemical etching device may be used to form a plurality of interconnection holes 510 at specified positions of the encapsulation structural body formed through step 40 by one or more of punching manners such as laser punching, photoetching, or chemical etching.

When the laser device is utilized to perform laser punching, the encapsulation structural body is fixed on a fixing device such as a chuck of a laser punching machine in a manner that one side formed with the chip 100 faces upward, and a plurality of interconnection holes 510 are formed by laser light at specified positions of the encapsulation structural body, with the interconnection holes reaching the upper surface of the part of the heat dissipation sheet 200 connected to the chip mounting region.

In the case of thinning by chemical etching, a plurality of interconnection holes 510, reaching the upper surface of the part of the heat dissipation sheet 200 connected to the chip mounting region, are formed by an etching device with an etching solution at specified positions of the encapsulation structural body. Specifically, a main component of the etching solution is potassium hydroxide, and other compounds such as accelerator may also be contained. The structural body is immersed in an etching tank accommodating the above chemical etching solution, to etch the encapsulation structural body, for example, performing etching with the help of a mask, thereby a plurality of interconnection holes 510 reaching the upper surface of the part of the heat dissipation sheet 200 connected to the chip mounting region are formed at specified positions of the encapsulation structural body.

Subsequently, as shown in FIG. 7B, the electrically conducting material layer 600 is formed at the interconnection holes 510, the encapsulation material layer 500, and a specified part of the front surface of the chip 100. For example, the electrically conducting material layer 600 electrically connecting predetermined pin(s) of the chip 100 with the heat dissipation sheet 200 is formed by using a mask or the like through electroless plating, electroplating, silk-screen/steel-mesh printing and so on generally known in the art.

In addition, it is also possible that the mask is not used, and first, the electrically conducting material layer is formed in the interconnection holes 510 and on the upper surface of the whole encapsulation material layer 500, and then unneeded parts are removed to form the electrically conducting material layer 600.

If it is the structural bodies shown in FIGS. 6D˜6H, i.e., the front surface of the chip 100 and the upper surface of a part of the heat dissipation sheet 200 to be electrically connected are both located in the same plane as the upper surface of the encapsulation material layer 500, the step of forming the interconnection holes 510 is omitted, and the electrically conducting material layer 600 is directly formed on the heat dissipation sheet 200, the encapsulation material layer 500, and a specified part of the surface of the chip 100, so that the predetermined pin of the chip 100 is electrically connected to the heat dissipation sheet 200.

Formation of the electrically conducting material layer 600 on the heat dissipation sheet 200, the encapsulation material layer 500, and a specified part of the front surface of the chip 100 is the same as the above, and description thereof is omitted herein.

As to the material forming the electrically conducting material layer, electrically conducting metal materials such as copper and aluminum can be listed, which is not particularly limited herein. The thickness of the electrically conducting material layer 600 is not particularly limited as long as the thickness can enable electrically connection of corresponding parts. In addition, as the front surface of the chip 100 and the upper surface of the encapsulation material layer 500 are located in the same plane, the formed electrically conducting material layer 600 protrudes from the front surface of the chip 100 and the upper surface of the encapsulation material layer 500, that is, the electrically conducting material layer 600 is grown in situ at a specified part (for example, a pin) of the chip 100. As viewed from above, the electrically conducting material layer 600 only needs to completely cover the specified part (for example, the pin) of the chip 100 and connect the same to the heat dissipation sheet 200, and the electrically conducting material layer may be designed in different shapes and different dimensions according to use conditions, which is not particularly limited herein.

Step S60, preparing a packaging circuit protection layer and a pin bonding pad.

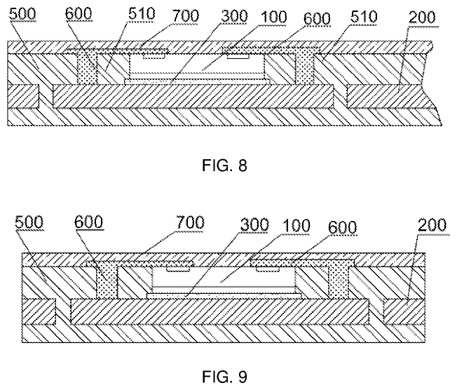

As shown in FIG. 8, the packaging circuit protection layer 700 is formed on the electrically conducting material layer 600, to protect the electrically conducting material layer 600 from external forces and the like. The packaging circuit protection layer 700 can adopt a generally known material such as a polymer or an inorganic insulating material, which is not particularly limited herein.

In FIG. 8, only a packaging body corresponding to the structural body shown in FIG. 7B is shown.

By a transfer mold device, a compress mold device, an inject mold device, a vacuum lamination device or the like that are generally known, in a state that the structural body formed with the electrically conducting material layer 600 is fixed on a fixing device such as a sucker of the mold device, a certain amount of protection material is supplied from a material supply unit of the mold device, to over one side of the electrically conducting material layer 600.

The pin bonding pad (not shown in drawings) is formed on the packaging circuit protection layer 700, which belongs to common general knowledge in the art, and illustration and description are omitted herein.

S70, performing cutting to obtain a device.

According to a device design, the packaging body obtained in step S60 is cut into a single device (the pin bonding pad is not shown) shown in FIG. 9.

As to a cutting method, laser cutting may be performed by a laser device, the structural body is fixed on a chuck of the laser device or the like, and the structural body is cut by laser light according to a specified trajectory, so as to obtain a plurality of devices according to circuit design.

In the above fan-out type packaging method, the packaging circuit and the packaging circuit protection layer are formed through in-situ growth of the electrically conducting material in specified parts of the chip, for example, the pins, the packaging circuit enabling a predetermined pin of the chip to be electrically connected with the heat dissipation sheet is formed, and the packaging circuit bonding pad having a dimension far larger than that of the pin of the chip is directly formed in a specified part, for example, a pin, of the chip, so that the thickness of the pin is greatly increased, the interconnection line is short, an effective electrically conducting area is large, and a larger current may be carried, then the interconnection reliability is high. In addition, the heat generated by the chip may be dissipated from the front surface, the back surface, and the side surface simultaneously through the heat dissipation sheet and the pin bonding pad of the package, significantly improving the heat dissipation performance. In addition, the package has small thermal resistance, may significantly reduce an operation temperature of devices, improve the reliability of packaged devices, may improve the operation power and reduce the power consumption of devices, and may integrate chips with a high power density. The dimension and thickness of the fan-out type package can also be reduced. The method for manufacturing this fan-out type package is simple, can reduce the cost, and reduce difficulty of the process.

Through combination of various steps, the package having only any one of the structures of FIG. 1A˜FIG. 1F may be prepared, or the package having two or more structures of FIG. 1A˜FIG. 1F also may be prepared, which is not particularly limited herein.

Finally, it should be noted that the above embodiments are merely specific embodiments of the present disclosure, for illustrating the technical solutions of the present disclosure, rather than limiting the present disclosure, and the scope of protection of the present disclosure should not be limited thereto. While the detailed description is made to the present disclosure with reference to the preceding embodiments, those ordinarily skilled in the art should understand that within the technical scope disclosed in the present disclosure, anyone familiar with the present technical field still could make modifications or readily envisage changes for the technical solutions recited in the preceding embodiments, or make equivalent substitutions to some of the technical features therein; these modifications, changes, or substitutions do not make the essence of corresponding technical solutions depart from the spirit and scope of the technical solutions of the embodiments of the present disclosure, and they all should be covered within the scope of protection of the present disclosure. Therefore, the scope of protection of the present disclosure should be determined by the scope of protection of the claims.

The present disclosure relates to the field of chip packaging, and can realize the fan-out type package capable of realizing good heat dissipation, improving operation power and reducing power consumption of devices, and being applicable to chips with a high power density, and a preparation method of the fan-out type package.

1. A fan-out type package, having one or more chips having same or different functions, an adhesive material layer, a heat dissipation sheet, an encapsulation material layer, a packaging circuit, and a packaging circuit protection layer which is configured for protecting the packaging circuit,
wherein a back surface of the chip is mounted to a chip mounting region of the heat dissipation sheet through the adhesive material layer;
a front surface of the chip is covered by a temporary protection material; the encapsulation material layer is formed by making an encapsulation material flow into and fill a gap between the temporary protection material and the heat dissipation sheet and/or cover a side of the heat dissipation sheet opposite to a side thereof mounted with the chip, and then removing the temporary protection material, thus the encapsulation material layer covers the chip, the adhesive material layer, and the heat dissipation sheet; and
the packaging circuit is formed by being grown on the front surface of the chip, the encapsulation material, and the heat dissipation sheet.

2. The fan-out type package according to claim 1, wherein the heat dissipation sheet has hollowed-out holes that are hollowed out in a thickness direction of the fan-out type package, and the hollowed-out holes are channels configured for allowing the encapsulation material constituting the encapsulation material layer to flow therethrough.

3. The fan-out type package according to claim 1, wherein in a thickness direction of the fan-out type package, a surface of the chip mounting region is located in a same horizontal plane as other regions of the heat dissipation sheet.

4. The fan-out type package according to claim 1, wherein in a thickness direction of the fan-out type package, a surface of the chip mounting region is higher than surfaces of other regions of the heat dissipation sheet.

5. The fan-out type package according to claim 1, wherein in a thickness direction of the fan-out type package, a surface of the chip mounting region is lower than surfaces of other regions of the heat dissipation sheet.

6. The fan-out type package according to claim 5, wherein the heat dissipation sheet is provided with a projection structure, and in the thickness direction of the fan-out type package, a surface of the projection structure is higher than the surface of the chip mounting region.

7. The fan-out type package according to claim 1, wherein in a thickness direction of the fan-out type package, the front surface of the chip is higher than a part of the heat dissipation sheet other than the chip mounting region, and the front surface of the chip is exposed from the encapsulation material layer in a manner of being located in a same plane as an upper surface of the encapsulation material layer.

8. The fan-out type package according to claim 6, wherein in the thickness direction of the fan-out type package, the front surface of the chip is located in a same plane as an upper surface of the projection structure of the heat dissipation sheet, and the front surface of the chip and the upper surface of the projection structure of the heat dissipation sheet are exposed from the encapsulation material layer in a manner of being located in a same plane as the upper surface of the encapsulation material layer, and
the packaging circuit is formed by being directly grown on the front surface of the chip, the upper surface of the encapsulation material layer, and the upper surface of the projection structure of the heat dissipation sheet.

9. The fan-out type package according to claim 7, wherein through holes are formed on the encapsulation material layer in the thickness direction, with the through holes vertically running from the upper surface of the encapsulation material layer to an upper surface of a part of the heat dissipation sheet connected to the chip mounting region, wherein the through holes are channels configured for allowing an electrically conducting material forming the packaging circuit to flow therethrough.

10. The fan-out type package according to claim 1, wherein the temporary protection material consists of a peelable glue and a temporary carrying sheet.

11. The fan-out type package according to claim 1, wherein two surfaces of the heat dissipation sheet are each mounted with a chip.

12. The fan-out type package according to claim 1, wherein the adhesive material is an electrically conducting material.

13. The fan-out type package according to claim 1, wherein the adhesive material is an insulating material.

14. The fan-out type package according to claim 1, wherein the adhesive material has thermal conductivity.

15. A preparation method of a fan-out type package, comprising:
a step of preparing a chip, in which a plurality of chips having same or different functions are prepared;
a step of preparing a heat dissipation sheet, in which a chip mounting region configured for mounting the chip and hollowed-out holes that are hollowed out in a thickness direction of the heat dissipation sheet are formed on the heat dissipation sheet;
a step of mounting the chip, in which a back surface of the chip is mounted through an adhesive material to the chip mounting region of the heat dissipation sheet;
an encapsulating step, in which the front surface of the chip is fixed with a temporary protection material, so that an encapsulation material is made to flow into and fill a gap between the temporary protection material and the heat dissipation sheet and/or cover a side of the heat dissipation sheet opposite to a side thereof mounted with the chip, and the temporary protection material is removed, to thus form the encapsulation material layer covering the chip, the heat dissipation sheet, and the adhesive material;
a step of preparing a packaging circuit, in which an electrically conducting material is grown on the front surface of the chip, the heat dissipation sheet, and the encapsulation material to form a packaging circuit layer;
a step of preparing a packaging circuit protection layer and a bonding pad, in which the packaging circuit protection layer configured for protecting the packaging circuit is produced on the packaging circuit, and the bonding pad of the package is formed on the packaging circuit protection layer; and
a step of performing cutting to obtain a device, in which a single packaged device is formed by cutting.

16. The preparation method of a fan-out type package according to claim 15, wherein in a thickness direction of the fan-out type package, a front surface of the chip mounted to the chip mounting region through the mounting step is higher than an upper surface of a part of the heat dissipation sheet other than the chip mounting region,
in an encapsulation structural body formed through the encapsulating step, the front surface of the chip is exposed from the encapsulation material layer in a manner of being located in a same plane as the upper surface of the encapsulation material layer, and the upper surface of the part of the heat dissipation sheet other than the chip mounting region is covered by the encapsulation material layer, and
in the step of preparing a packaging circuit, through holes are formed on the encapsulation material layer in the thickness direction, with the through holes vertically running from the upper surface of the encapsulation material layer to the upper surface of the part of the heat dissipation sheet connected to the chip mounting region, and an electrically conducting material forming the packaging circuit flows in the through holes to reach the upper surface of the part of the heat dissipation sheet connected to the chip mounting region.

17. The preparation method of a fan-out type package according to claim 15, wherein in the step of preparing a heat dissipation sheet, a projection structure is formed on the heat dissipation sheet, and in the thickness direction of the fan-out type package, a surface of the projection structure is higher than a surface of the chip mounting region,
in the thickness direction of the fan-out type package, the front surface of the chip mounted to the chip mounting region through the mounting step is located in a same plane as the upper surface of the projection structure of the heat dissipation sheet, in an encapsulation structural body formed through the encapsulating step, the front surface of the chip is exposed from the encapsulation material layer in a manner of being located in a same plane as the upper surface of the encapsulation material layer, and the upper surface of the projection structure of the heat dissipation sheet is exposed from the encapsulation material layer in a manner of being located in the same plane as the upper surface of the encapsulation material layer, and
in the step of preparing a packaging circuit, the packaging circuit is formed by being directly grown on the front surface of the chip, the projection structure of the heat dissipation sheet exposed from the encapsulation material layer, and the encapsulation material layer.

18. The preparation method of a fan-out type package according to claim 15, wherein in the step of preparing a heat dissipation sheet, in the thickness direction, thickness of the chip mounting region of the heat dissipation sheet is reduced, so that the chip mounting region is lower than upper surfaces of other parts of the heat dissipation sheet.

19. The preparation method of a fan-out type package according to claim 15, wherein in the encapsulating step, the temporary protection material is a temporary carrier, and the front surface of the chip is fixed, by bonding, with the temporary carrier.

20. The fan-out type package according to claim 1, wherein in a thickness direction of the fan-out type package, the front surface of the chip is higher than a part of the heat dissipation sheet other than the chip mounting region, and the front surface of the chip is exposed from the encapsulation material layer in a manner of being located in a same plane as an upper surface of the encapsulation material layer.
